(19) United States
(12) Patent Application Publication
(10) Pub. No.: US 2025/0231227 A1
(43) Pub. Date: Jul. 17, 2025

(54) DETERMINING TRANSIENT STABILITY OF A POWER GRID USING A QUANTUM COMPUTING SYSTEM

(71) Applicant: ColdQuanta, Inc., Boulder, CO (US)

(72) Inventors: Eric Brandon Jones, Golden, CO (US); Pranav Gokhale, Chicago, IL (US)

(73) Assignee: ColdQuanta, Inc., Boulder, CO (US)

(21) Appl. No.: 19/015,223

(22) Filed: Jan. 9, 2025

Related U.S. Application Data
(60) Provisional application No. 63/551,790, filed on Feb. 9, 2024.
(60) Provisional application No. 63/620,863, filed on Jan. 14, 2024.

(51) Int. Cl. G01R 19/25; G06N 10/20; G06N 10/40

(52) U.S. Cl. CPC G01R 19/2513; G06N 10/20; G06N 10/40

(57) ABSTRACT

A method for determining transient stability of a power grid using qubits of a quantum computing system comprises: receiving input parameters associated with a portion of the power grid; preparing an initial quantum state based on the input parameters; determining a plurality of time evolution steps, where each time evolution step is associated with a different respective iteration of a plurality of iterations; applying, for each iteration, a first set of quantum gate operations (QGOs) to the qubits, wherein the first set of QGOs produces a quantum state based on a first evolution of the initial quantum state or a quantum state produced by a previous iteration, and a second set of QGOs to the qubits, wherein the second set of QGOs produces a quantum state based on a second evolution of the quantum state produced by the first set of QGOs of a respective iteration.

### CROSS-REFERENCE TO RELATED APPLICATION(S)

This application claims priority to and the benefit of U.S. Provisional Application Ser. No. 63/620,863, entitled “EXPONENTIAL QUANTUM ADVANTAGE IN MODELING POWER GRID GENERATOR SWING AND AUTONOMOUS AGENT SYNCHRONIZATION,” filed Jan. 14, 2024, and U.S. Provisional Application Ser. No. 63/551,790, entitled “EXPONENTIAL QUANTUM ADVANTAGE IN TRANSIENT STABILITY ANALYSIS,” filed Feb. 9, 2024, the entire disclosure of which is hereby incorporated by reference.

### TECHNICAL FIELD

This disclosure relates to determining transient stability of a power grid using a quantum computing system.

### BACKGROUND

Transient stability analysis (TSA) is the mathematical field concerned with the short-time restoration of a power grid to equilibrium operating conditions after a disturbance such as a generator failure or line outage and can be used to mitigate against catastrophic state changes, such as blackouts and cascading failures. In some examples, given a model of the power grid, TSA can assess how long it will take, or even if, the power grid will resume voltage, frequency, or rotor angle synchronism after the occurrence of a contingency, e.g., the sudden and potentially widespread change in grid parameters or network topology. TSA therefore can classify whether a contingency is safe or unsafe based on mathematical analytics and computer simulation.

### SUMMARY

In one aspect, in general, a method for determining transient stability of a power grid using one or more qubits of a quantum computing system comprises: receiving input parameters associated with at least a portion of the power grid; preparing an initial quantum state associated with the one or more qubits based at least in part on the input parameters; determining a plurality of time evolution steps, where each time evolution step of the plurality of time evolution steps is associated with a different respective iteration of a plurality of iterations; applying, for each iteration of the plurality of iterations, a first set of one or more quantum gate operations to the one or more qubits, wherein the first set of one or more quantum gate operations produces a quantum state that is based at least in part on a first evolution of the initial quantum state or a quantum state produced by a previous iteration of the plurality of iterations, and a second set of one or more quantum gate operations to the one or more qubits, wherein the second set of one or more quantum gate operations produces a quantum state that is based at least in part on a second evolution of the quantum state produced by the first set of one or more quantum gate operations of a respective iteration; and determining the transient stability of the power grid based at least in part on one or more properties of a quantum state produced by an iteration of the plurality of iterations.

Aspects can include one or more of the following features.

The power grid comprises a plurality of nodes including one or more power supply nodes and one or more power consumption nodes interconnected by power transmission lines, the first evolution corresponds to propagation of waveforms over one or more of the power transmission lines.

The second evolution corresponds to damping of waveforms at one or more of the plurality of nodes.

The input parameters are based at least in part on a Kuramoto model.

The first evolution of the initial quantum state or a quantum state produced by a previous iteration of the plurality of iterations corresponds to a real-time evolution of the initial quantum state or the quantum state produced by a previous iteration of the plurality of iterations.

The second evolution of the quantum state produced by the first set of one or more quantum gate operations of a respective iteration corresponds to an imaginary-time evolution of the quantum state produced by the first set of one or more quantum gate operations of a respective iteration.

The one or more qubits comprises at least two qubits and a first quantum gate operation of the second set of one or more quantum gate operations comprises entangling a first subset of the at least two qubits with a second subset of the at least two qubits.

The second quantum gate operation of the second set of one or more quantum gate operations comprises measuring one or more quantum states, where each quantum state is associated with a respective qubit of the first subset of the at least two qubits.

The second set of one or more quantum gate operations produces the quantum state based at least in part on a result of the measurement of the one or more quantum states.

At least one quantum gate operation of the first set of one or more quantum gate operations comprises a rotation operation to one or more qubits.

At least one quantum gate operation of the first set of one or more quantum gate operations comprises a controlled unitary operation between a first qubit of the one or more qubits and a second qubit of the one or more qubits.

The first set of one or more quantum gate operations comprises alternating controlled unitary operations between the first qubit of the one or more qubits and the second qubit of the one or more qubits and rotation operations applied to the second qubit of the one or more qubits.

The controlled unitary operations comprise controlled not (CNOT) operations.

The second set of quantum gate operations comprises Hadamard gates applied to each qubit of the one or more qubits.

Each gate operation of the first set of one or more quantum gate operations is applied to either one qubit of the one or more qubits or two qubits of the one or more qubits.

In another aspect, in general, a system configured for determining transient stability of a power grid using one or more qubits of a quantum computing system comprises: a power grid comprising one or more power supply nodes and one or more power consumption nodes interconnected by power transmission lines; an interface module in communication with the quantum computing system configured to manage an analysis process, the management comprising: receiving input parameters associated with at least a portion of the power grid; preparing an initial quantum state associated with the one or more qubits based at least in part on the input parameters; determining a plurality of time evolution steps, where each time evolution step of the plurality of time evolution steps is associated with a different respective iteration of a plurality of iterations; sending to the quantum computing system a specification defining the plurality of iterations performed by the quantum computing system, wherein each iteration of the plurality of iterations comprises, a first set of one or more quantum gate operations applied to the one or more qubits, wherein the first set of one or more quantum gate operations produces a quantum state that is based at least in part on a first evolution of the initial quantum state or a quantum state produced by a previous iteration of the plurality of iterations, and a second set of one or more quantum gate operations applied to the one or more qubits, wherein the second set of one or more quantum gate operations produces a quantum state that is based at least in part on a second evolution of the quantum state produced by the first set of one or more quantum gate operations of a respective iteration; and determining the transient stability of the power grid based at least in part on a result received by the quantum computing system indicating one or more properties of a quantum state produced by an iteration of the plurality of iterations.

Aspects can include one or more of the following features.

The first evolution corresponds to propagation of waveforms over one or more of the power transmission lines.

The second evolution corresponds to damping of waveforms at one or more of the plurality of power supply nodes.

The input parameters are based at least in part on a Kuramoto model.

The first evolution of the initial quantum state or a quantum state produced by a previous iteration of the plurality of iterations corresponds to a real-time evolution of the initial quantum state or the quantum state produced by a previous iteration of the plurality of iterations.

Aspects can have one or more of the following advantages.

In some implementations, a quantum computer can be used to perform TSA of a power grid. In some examples, operations performed by a quantum computer can be associated with performing computations or calculations of a system evolving in time. In some examples, using a quantum computer to model a power grid can be more efficient and less time intensive than modeling with a classical computer. Some of the methods and systems disclosed herein can be associated with higher efficiencies of computational power in performing numerical simulations.

Other features and advantages will become apparent from the following description, and from the figures and claims.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a schematic diagram of an example power grid.

FIG. 2 is a schematic diagram of an example system.

FIG. 3 is a flowchart of an example method.

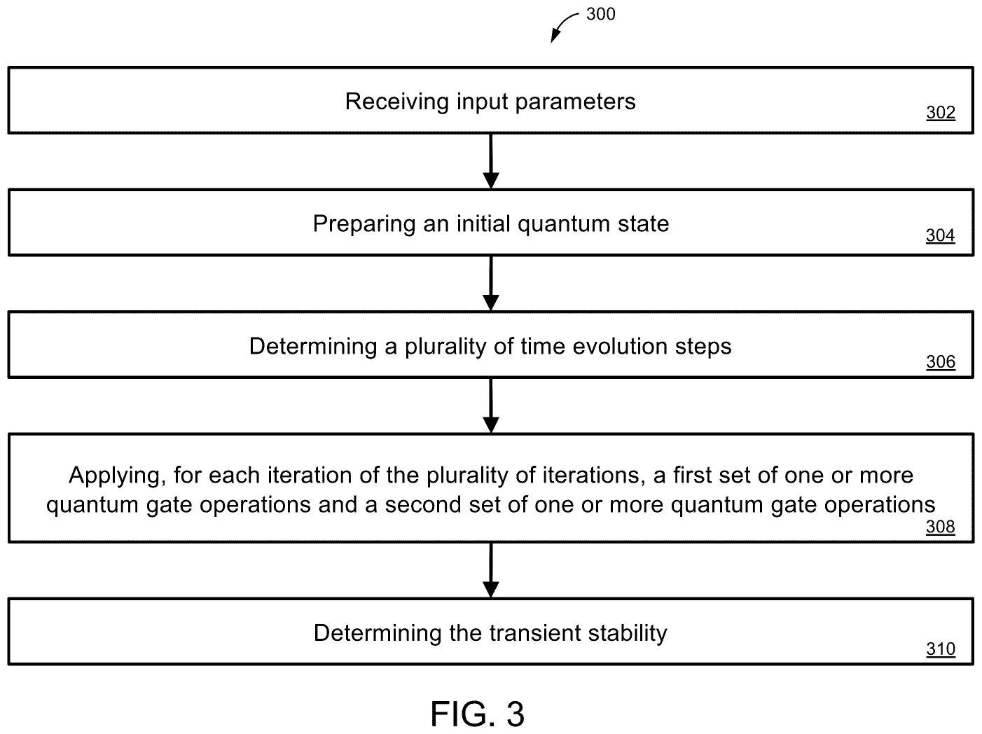

### DETAILED DESCRIPTION

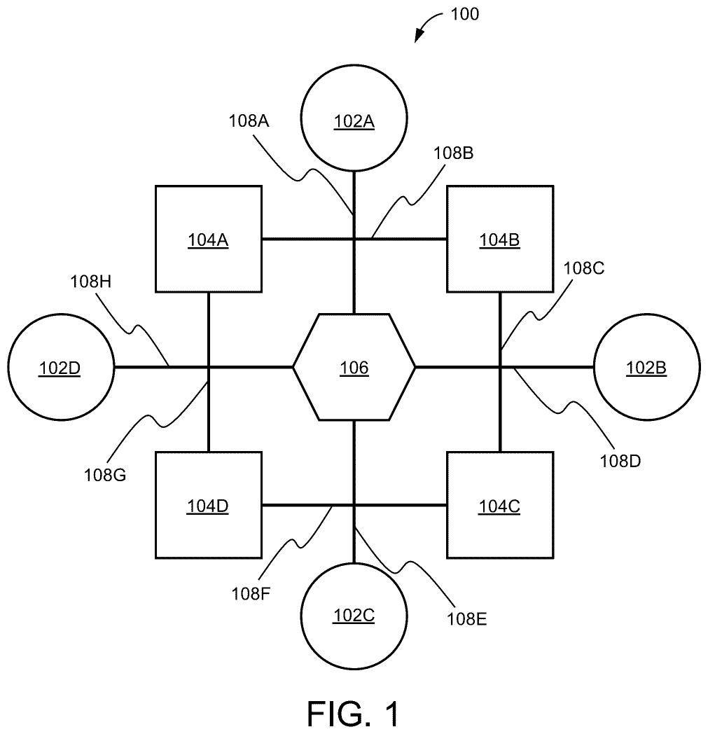

FIG. 1 depicts an example power grid 100 comprising a plurality of nodes 102A-102D, 104A-104B, 106 interconnected by power transmission lines 108A-108H. In some examples, the plurality of nodes can include one or more power supply nodes 102A-102D and one or more power consumption nodes 104A-104D. Some power supply nodes can be power generation facilities or “power plants.” Some examples of power generation facilities include solar power plants, wind farms, thermal power plants, and hydroelectric power plants. Some examples of power consumption nodes include commercial buildings, smart transport, smart houses, consumer buildings, and factories. Some power grids can include one or more nodes that are not associated with power supply or power consumption. For instance, some power grids can include a distributed energy resource management node 106 that is configured to distribute power from one or more power supply nodes 102A-102D to respective power consumption nodes 104A-104D. Some power grids can also include power distribution nodes (not shown), such as repeater stations, that are configured to extend power distribution capabilities of the power grid. In some examples, a power grid can be associated with propagation of waveforms between nodes of the plurality of nodes.

In some examples, numerical simulations associated with a power grid can be performed on a system comprising a quantum computer. Some quantum computers or quantum computing systems can be configured to execute quantum operations by storing and manipulating quantum states associated with a set of connected quantum bits, also called qubits. Each qubit can correspond to a quantum system described by quantum states and can be initialized, or brought into a superposition, of these quantum states. Some quantum states can be mathematically represented by a wave function. When measured, the wave function associated with a qubit can collapse into one of the states in the superposition according to a probability described by the wave function.

Some quantum computers can manipulate quantum states associated with a system of qubits. For instance, a single-qubit gate can be used to apply a quantum operation that changes the state of a single qubit. A qubit can also be entangled with one or more other qubits. A multi-qubit gate, for instance two-qubit gate, can be used to apply a quantum operation that changes the states of qubits at its input, for example, to entangle multiple qubits or change the states of the qubits. Combinations of quantum logic gates and measurement can enable the realization of quantum algorithms.

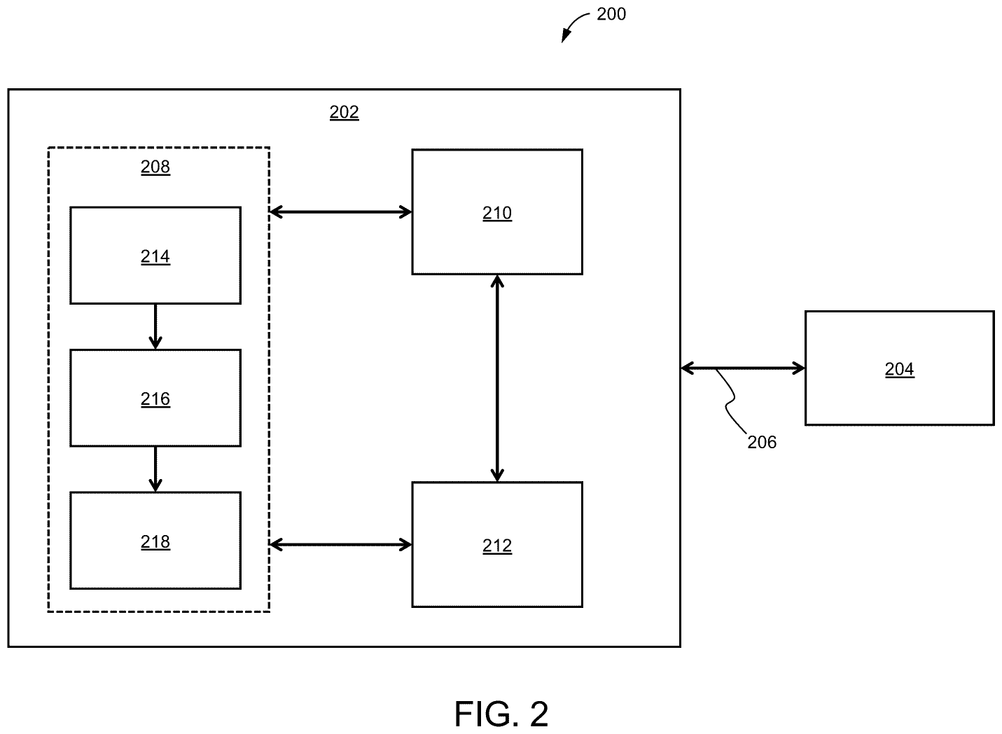

FIG. 2 depicts an example system 200 comprising a quantum computing system 202 and an interface module 204 that are in communication via interface 206. The quantum computing system 202 comprises a quantum hardware module 208, a processor 210, and a memory 212. The quantum hardware module 208 comprises qubits 214, logic gates 216, and readout units 218. In some examples, the processor 210 can be configured to operate the quantum hardware module 208 and the memory 212 can store information associated with the quantum hardware module 208. The processor 210 and the memory 212 can also be in communication with each other.

In some examples, an interface module and a quantum computing system can be located in physical proximity. In some examples, a quantum computing system can be located in a first location and an interface module can be located in a second location that is different than the first location. In some examples, a power grid can be located in a third location that is different than the first location and the second location.

Without intending to be bound by theory, the following is an example of a theoretical model for illustrating features. In some examples, the transient stability of a power grid can be modeled or understood by simulating the quench dynamics of the classical swing equations. For a set of generators on the power grid, swing equations can be a set of ordinary differential equations that govern the time evolution of generator phase angles. In some examples, these differential equations can be isomorphic, in their most general form, to a set of damped (potentially driven), non-linearly (usually sinusoidally) coupled classical oscillators:

$${M}_{i} {\ddot{θ}}_{ι} + {D}_{i} {\dot{θ}}_{ι} = {ω}_{i} - {\sum }_{j = 1}^{N} {a}_{i j} sin ( {θ}_{i} - {θ}_{j} - {φ}_{i j} ) \qquad ( 1 )$$

The Mᵢ, Dᵢ, and ωᵢ are the generators' moments of inertia, damping constants, and effective power input, respectively. The aᵢⱼ and φᵢⱼ correspond to the maximum power transfer between and transfer conductance energy loss phase shift between generators i and j, respectively. In this context, transient stability can be equivalent to assessing the stability of a synchronized frequency equilibrium (i.e., \dot{θ}ᵢ=\dot{0}ⱼ for all i, j) under changes in the swing equation network (i.e., grid) topology or parameters. If all generators obtain this frequency equilibrium and the differences in their phase angles, |θᵢ−θⱼ|, are also bounded, the generators can be said to be in synchronous equilibrium. In some implementations, the analysis of swing equations can be performed in a co-rotating frame such that the frequency synchronization condition is formulated as \dot{θ}ᵢ=0∀i. The simulation of swing equations for large, realistically sized power grids can be computationally intensive. Hence, simulating swing equations, or variants thereof, in a more efficient manner could lead to drastically better grid design, control, and resiliency.

Two other equations, the consensus protocol equation and the Kuramoto model, can describe the more general synchronization problem of N autonomous agents. In some examples, these equations can be closely related to the swing equations and can be similarly challenging to solve. The consensus protocol equation can take the form:

$${\dot{x}}_{i} = - {\sum }_{i = 1}^{N} {a}_{i j} ( {x}_{i} - {x}_{j} )$$

and the (non-uniform) Kuramoto model can take the form:

$${D}_{i} {\dot{θ}}_{ι} = {ω}_{i} - {\sum }_{j = 1}^{N} {a}_{i j} sin ( {θ}_{i} - {θ}_{j} - {φ}_{i j} )$$

which can describe a wide array of synchronization phenomena across biology, physics, and computer science. In some examples, the swing equations, the consensus protocol, or the Kuramoto model can be performed on a quantum computer.

Some quantum computers can be used to simulate the time dynamics of a system of coupled classical harmonic oscillators,

$${m}_{j} {\ddot{x}}_{j} = {\sum }_{k \neq j} {κ}_{j k} ( {x}_{k} - {x}_{j} ) - {κ}_{j j} {x}_{j}$$

and can be associated with an exponential speedup versus a classical simulation of the system. In some implementations, simulating the time dynamics using a quantum computer can rely on the reduction of the dynamical equations of a system of N coupled classical harmonic oscillators to the Schrödinger equation for the time evolution of poly (n=log₂ N) qubits.

$$iℏ \vert \dot{ψ} 〉 = H \vert ψ 〉$$

In transient stability analysis, an example of a contingency can be a generator going down, e.g., a wind turbine is struck by lightning, or a power line going down. In other words, a contingency can be associated with a dampening of waveforms at one or more nodes of a power grid. In some examples, a generator going down can set one of the input power coefficients, ωᵢ, to zero in the swing equation. In some examples, a line being cut can set one of the adjacency matrix elements, aᵢⱼ, to zero in the swing equation. One or both contingencies can change the operator, Eq. 6, that the state vector, Eq. 5 (shown later in this disclosure), is evolving under—the resulting dynamics can be referred to as “quench dynamics”. If the state vector that holds the oscillator positions and velocities approximately resumes what it was doing before the contingency after a reasonably short time, then that contingency can be classified as “safe”. If the state vector takes too long to resume its previous orientation, or if it goes somewhere else entirely, that contingency can be classified as “unsafe” or “potentially unsafe.”

Results of TSA can be used to suggest corrective action. While analytic techniques can approximately decide if a grid will return to synchronism, numerical simulation can be used in order to determine how long a perturbed system will take to return to equilibrium. The described techniques can be used by a power grid operator to determine possible unsafe contingencies and how best to avoid or prevent the unsafe contingencies. For example, prior to any contingency taking place, various contingencies, such as every contingency, every possible combination of contingencies, every likely contingency, or every likely combination of contingency, can be analyzed to determine which contingencies can be classified as unsafe or potentially unsafe.

A power systems operator can simulate or screen possible (or likely) contingencies to see which ones have the worst outcomes. In some examples, a power systems operator can screen every possible or likely contingency to see which contingencies are associated with the worst outcomes. A power grid operator can then dream up corrective actions for those contingencies and screen which ones of those (via time to resynchronization) present the best option for restoring the system to equilibrium.

Described below are examples of numerical simulations in TSA using quantum computers that can be exponentially more efficient than numerical simulations using classical computers, thereby enabling the modeling of exponentially larger and more realistic electrical grids with much larger deployments of low-inertia, renewable power sources. Such simulations address a way to retire the risk for grid instability due to decarbonization.

Decarbonization of the power grid implies more renewable energy and less fossil-based energy. Fossil-fuel-based electricity sources introduce what is called “inertia” to the grid, because they typically use large, electro-mechanical generators that have a lot of mechanical inertia in combination with burning something (e.g., coal, gas) and boiling water to drive a steam turbine. Higher grid inertia is associated with better transient stability. Renewables, by contrast, do not typically operate by driving large generators. Wind turbines have generators, but they are smaller, and solar panels produce DC electricity that is converted to AC electricity through inverters and so do not involve electro-mechanical generators at all. These resources therefore have lower inertia, which means that when there is a contingency, there is the potential for the grid to become transiently unstable. As the grid becomes cleaner, there will be more potential for transient instabilities to occur, which means it will be more important to simulate contingencies efficiently beforehand as described below to be able to design and operate the grid with fewer interruptions of power.

In some examples, a coupled, multi-generator swing equation can be used as a model for performing numerical TSA. The coupled, multi-generator swing equation can be equivalent to the equation for a system of non-linearly coupled, dissipative mechanical oscillators. Some quantum computer algorithms can simulate the time dynamics of a system of coupled classical oscillators exponentially faster than any possible classical (i.e., conventional supercomputer) algorithm to perform the same simulation. This numerical simulation of the swing equation and related models can unlock the ability to perform TSA on power grid models with exponentially-more degrees of freedom (e.g., generators, loads) or exponentially faster screening of contingencies at fixed system size. An exponentially improved ability to perform TSA for realistic power system models in the presence of pervasive renewables can have multiple benefits: (i) reduced energy-related emissions coming from the grid, (ii) improved energy efficiency of the grid (e.g., fewer idling or reserve resources are needed if contingencies can be accurately screened) feeding into any economic area dependent on grid electricity, and (iii) improved resilience, reliability, and security of the grid.

A variety of analytical methods have been devised to perform TSA and decide whether certain contingencies are either safe or unsafe in the small-system limit and approximately for larger systems. These known methods are insufficient either because they are limited to power systems with very few degrees of freedom and do not reflect the complexity or scale of real-world power grids or because the approximations involved in categorizing safe versus unsafe contingencies make the predictions only qualitative, while quantitative categorization is imperative to safely operate a real grid. To perform quantitative TSA, various disclosed examples use direct numerical simulation of large-scale models, such as the swing equation, in the absence of unphysical assumptions. It is well-known that any classical algorithm that solves for the time-evolution of the coupled oscillator problem, and hence the swing equation, has runtime that is polynomial in the number of degrees of freedom of the problem. While not a strictly prohibitive runtime for the roughly 26,000 electrical generators that currently comprise the U.S. electrical grid, simulating the swing equation for smart grid architectures with bidirectional energy flow and potentially millions or billions of distributed renewable energy resources would prove impossible using conventional methods. Moreover, an exponential reduction in swing equation simulation runtime, from polynomial to polylogarithmic, enables an exponential runtime reduction in the classification of potential contingencies, whatever the system size in question. This runtime reduction unlocks the ability to quickly screen corrective contingencies to restore a system to synchronism after a fault.

In one example of TSA, a simulation can start at a time t₀ with the system in synchronous equilibrium in the co-rotating frame at the synchronous frequency. While the sinusoidal coupling on the right-hand side of Eq. 1 shown above can lead to chaotic behavior that implies a transient instability, a useful classification of a contingency can be obtained using a small-angle linearized interaction by flagging overdamped and critically damped solutions as “safe” while flagging underdamped solutions as “potentially unsafe”. Moreover, the constant terms in Eq. 1 can be removed by performing another change of variables such that Eq. 1 reduces to a homogenous, linear, second-order differential equation for the vector of rotor angles θ(t),

$$M \ddot{θ} + D \dot{θ} + A θ = 0 , \qquad ( 2 )$$

where M is a diagonal inertia matrix, D a diagonal damping matrix and A the maximum power transfer matrix. Because M is trivially invertible (full diagonal matrix), another change of variables, y=\sqrt{M}θ, \tilde{D}=\sqrt{M}⁻¹D\sqrt{M}⁻¹, Ã=\sqrt{M}⁻¹A\sqrt{M}⁻¹, can be performed to obtain:

$$\ddot{y} + \tilde{D} \dot{y} + \tilde{A} y = 0. \qquad ( 3 )$$

Some universal quantum computers that can efficiently perform real-time and imaginary-time evolution can efficiently simulate the Schrödinger-like equation

$$\frac{d}{d t} \vert ψ 〉 = - iH \vert ψ 〉 \qquad ( 4 )$$

where H=H_{H}+H_{A} is the decomposition of a generic complex-valued operator into its Hermitian and anti-Hermitian components. Consider the quantum state-vector encoding of the variables in Eq. 3, with B and N×M matrix satisfying BB^{†}=Ã,

$$\vert ψ ( t ) 〉 = \frac{1}{\sqrt{2 E ( t )}} ( \begin{matrix}\dot{y} ( t ) \\ {iB}^{†} y ( t )\end{matrix} ) , \qquad ( 5 )$$

where the oscillator energy, E(t), is time-dependent due to dissipation. On direct substitution of Eq. 5 into Eq. 4, and using Eq. 3 to re-write the acceleration term, Eq. 5 can undergo Schrödinger-like evolution under the operator:

$$H = - \frac{i}{2} \frac{\dot{E} ( t )}{E ( t )} 𝕀 - ( \begin{matrix}0 & B \\ {B}^{†} & 0\end{matrix} ) - ( \begin{matrix}i \tilde{D} & 0 \\ 0 & 0\end{matrix} ) . \qquad ( 6 )$$

The first term in Eq. 6 is anti-Hermitian but proportional to the identity and so only can induce a global renormalization in the time evolution. The second term can induce real-time, Hermitian, oscillatory evolution, and the last term can induce anti-Hermitian, dissipative dynamics. Taken together, Eqs. 3-6 prove that the linearized swing equation can be efficiently simulated on a universal quantum computer using a combination of real-time and imaginary-time evolution. The Trotter-approximated (here l Trotter steps and a first-order product formula for each step are used, but the methodology covers instances where higher-order product formulas are used) non-unitary propagator corresponding to the formal solutions of Eqs. 4-6 is

$$U ( t , {t}_{0} = 0 ) \approx \sqrt{\frac{E ( 0 )}{E ( t )}} {( exp \{ - ( \begin{matrix}\tilde{D} & 0 \\ 0 & 0\end{matrix} ) Δ t \} exp \{ i ( \begin{matrix}0 & B \\ {B}^{†} & 0\end{matrix} ) Δ t \} )}^{l} . \qquad ( 7 )$$

In some examples, implementing Eq. 7 in a quantum algorithm can comprise applying alternating steps of real-time evolution, as represented by the term

$$exp \{ i ( \begin{matrix}0 & B \\ {B}^{†} & 0\end{matrix} ) Δ t \} ,$$

and imaginary-time evolution, represented by the term

$$exp \{ - ( \begin{matrix}\tilde{D} & 0 \\ 0 & 0\end{matrix} ) Δ t \} .$$

As an example, for l=2, Eq. 7 can take the form

$$U ( t , {t}_{0} = 0 ) \approx \sqrt{\frac{E ( 0 )}{E ( t )}} ( exp \{ - ( \begin{matrix}\tilde{D} & 0 \\ 0 & 0\end{matrix} ) Δ t \} exp \{ i ( \begin{matrix}0 & B \\ {B}^{†} & 0\end{matrix} ) Δ t \} exp \{ - ( \begin{matrix}\tilde{D} & 0 \\ 0 & 0\end{matrix} ) Δ t \} exp \{ i ( \begin{matrix}0 & B \\ {B}^{†} & 0\end{matrix} ) Δ t \} ) .$$

Each exponential term in the operator above, beginning with the rightmost term, can then sequentially operate on an initial state to produce a respective quantum state. Given a plurality of time evolution steps, or l Trotter steps, a plurality of iterations associated with performing computations on a quantum computer can be determined, where each time evolution step of the plurality of time evolution steps is associated with a different respective iteration of the plurality of iterations.

For each iteration of the plurality of iterations, two sets of one or more quantum gate operations can be performed by the quantum computer. The first set of quantum gate operations can produce a quantum state that is based at least in part on a first evolution of an initial quantum state or a quantum state produced by a previous iteration of the plurality of iterations, as represented by the Hermitian terms in Eq. 6 or the unitary part of Eq. 7. In some examples, the first evolution of a quantum state can be associated with a real-time evolution of the quantum state. The second set of quantum gate operations can produce a quantum state that is based at least in part on a second evolution of the quantum state produced by the first state of the one or more quantum gate operations of a respective iteration, as represented by the anti-Hermitian terms in Eq. 6 or the non-unitary part of Eq. 7. In some examples, the second evolution of a quantum state can be associated with an imaginary-time evolution of the quantum state.

In some examples, a quantum computer can simulate a unitary operator by decomposing the unitary operator into a series of products of smaller unitary operations, or quantum gates. In various examples, using the equations discussed above, if the oscillator masses and spring constants can be efficiently queried, and if the initial state of the dynamics can be efficiently prepared, the complexity of simulating the Hermitian part of Eq. 6 (or equivalently, the unitary part of Eq. 7) can be polynomial in n, nearly linear in evolution time, and sublinear in the sparsity. This linearity can arise from the efficient simulation of the Schrödinger equation on a quantum computer by discretization methods such as qubitization. In some examples, an exponential quantum advantage of simulating coupled classical harmonic oscillators can be accomplished by discretization of the Schrödinger equation on a quantum computer. In some implementations, simulating the oscillatory component of the swing equations as a concrete application can be referred to “real-time quantum simulation” (RTQS).

In addition to the RTQS algorithm, some quantum computers can also perform “imaginary-time quantum simulation” (ITQS) that can treat the anti-Hermitian terms in Eq. 6 (or equivalently, the non-unitary part of Eq. 7). As described below, various implementations can additionally leverage ITQS to simulate the time dynamics of the consensus protocol and Kuramoto model equations.

Disclosed examples can leverage ITQS to integrate the time evolution of the Kuramoto model and consensus protocol equations on a quantum computer. Other examples can leverage RTQS to integrate the time evolution of the swing equations on a quantum computer. In each case, the use of a quantum computer to perform the time integration of the differential equations can result in an exponential scaling advantage over the best possible classical algorithm for performing the integration. In the case of the Kuramoto model and consensus protocol equations, integration of the differential equation can be aimed at answering questions surrounding different levels of synchronization of the agents. In the case of the swing equations, integration of the differential equation can be aimed at understanding the transient stability of an associated power grid by assessing how long it takes for the system to resume frequency synchronization or synchronous equilibrium after perturbations in the grid topology or parameters. Various disclosed examples, therefore, can enable exponentially more efficient design and control of power grids and systems of interacting autonomous agents.

Various disclosed examples can perform time integration of the swing equations, Kuramoto model, and consensus protocol equations on a quantum computer. Depending upon which system is under study and what synchronization condition is of interest, differential equation state variables can be encoded in slightly different ways in the quantum state vector amplitude.

Consider first the swing equations. Let θ(t₀) and \dot{θ}(t₀) be the vectors containing all swing equation phase angles and angular velocities, respectively, at the time t₀ at which a grid disturbance occurs. In the limit of small relative angular displacements and the power balance condition manifold Dᵢ\dot{θ}ᵢ−ωᵢ−Σⱼaᵢⱼφᵢⱼ=0 or Dᵢ\dot{θ}ᵢ=0 then up to constant terms the swing equation reduces exactly to the coupled harmonic oscillator equation. In these limits, a purely-quadratic, conserved energy function can be associated with the swing equations.

$$E = \frac{1}{2} {\sum }_{i} {M}_{i} {\dot{θ}}_{i}^{2} + \frac{1}{2} ( {\sum }_{i} {a}_{i i} {θ}_{i}^{2} + {\sum }_{j > i} {{a}_{i j} ( {θ}_{i} - {θ}_{j} )}^{2} ) = \frac{1}{2} {\dot{θ}}^{T} M \dot{θ} + \frac{1}{2} {μ}^{T} μ = K ( t ) + U ( t ) \qquad ( 8 )$$

where \dot{θ} is a vector containing the N angular velocities, M is a diagonal matrix containing N moments of inertia, and μ is a vector whose first N entries are \sqrt{aᵢᵢ}θᵢ and remaining N(N−1)/2 entries are \sqrt{aᵢⱼ}(θᵢ−θⱼ). In some examples, each of the vectors can be time-dependent. The vectoral degrees of freedom can be organized into a quantum state vector.

$$\vert ψ ( t ) 〉 = \frac{1}{\sqrt{2 E}} \vert \begin{matrix}\sqrt{M} \dot{θ} ( t ) \\ i μ ( t )\end{matrix} \qquad ( 9 )$$

Given an efficiently-preparable input state |ψ/(t₀) [symbol] , some algorithms can efficiently prepare |ψ/(t) [symbol] (via the integration of the swing equations by reduction to the Schrödinger equation), and measurements on |ψ(t) [symbol] can efficiently estimate K(t)/E and U(t)/E. In some examples, if the simulation is performed in the average frequency co-rotating frame, then the resumption of frequency equilibrium can be equivalent to the condition \dot{θ}ᵢ=0 for all generators i. Since the kinetic and total energies are non-negative, and since each term in the kinetic energy is non-negative, the following condition can allow one to determine after what time (or if) frequency equilibrium has been reestablished.

$$\frac{K ( t )}{E} = 0 ⟹ \dot{θ} ( t ) = 0 \qquad ( 10 )$$

In addition to determining if frequency equilibrium has been reestablished, K(t)/E=0 implies that U(t)/E=1. Since generators do not transfer power to themselves, aᵢᵢ=0. This result can mean that at frequency equilibrium, 2E=Σ_{j>i}aᵢⱼ (θᵢ−θⱼ)², establishing a bound for relative angular displacements, thereby also indicating that synchronous equilibrium has been achieved.

In some implementations of the consensus protocol equations, the equations can be re-written as

$$\dot{x} ( d ) = - L ( {a}_{i j} ) x ( t ) \qquad ( 11 )$$

where x(t) is a time-dependent vector containing the agent state variables, aᵢⱼ contains the interaction between agents i and j, and L(aᵢⱼ) is the Laplacian of the agent-agent interaction graph. For most agent-agent interactions, the interaction graph (i.e., adjacency matrix) can be taken to be simple and undirected. In this case, the Laplacian is symmetric, L^{T}=L. Note that symmetric matrices are a subset of Hermitian matrices. Next, Wick rotation may be performed to imaginary time, t→iτ, so that the consensus protocol equations become:

$$\dot{x} ( τ ) = - i L ( {a}_{i j} ) x ( τ ) \qquad ( 12 )$$

which can be equivalent to the Schrödinger equation in imaginary time. Hence, the consensus protocol equations can be integrated on a quantum computer using imaginary time evolution on a quantum computer, which may use ancilla qubits, mid-circuit measurement, or dissipative engineering. Consensus can be reached when all agent state variables reach a common value, xᵢ(t)→xₐᵥₑ. A (normalized) agent state variable in a quantum amplitude can therefore be encoded in a quantum amplitude using log₂ N qubits |ψ/(τ) [symbol] ∝|x(τ) [symbol] . Consensus can be reached when all amplitudes take on the same value, i.e., |ψ(τ) [symbol] →Σ_{z}|z [symbol] /N, the even superposition of all computational basis states. Convergence to this state at time t can be checked by appending a Hadamard gate to every qubit and checking that each qubit reads out to zero in the computational basis with unit probability.

To simulate the Kuramoto model, some examples can linearize the interaction term so that, up to constant terms, the interaction term can be equivalent to the consensus protocol.

FIG. 300 depicts an example method 300 for determining transient stability of a power grid using one or more qubits of a quantum computing system. The method 300 comprises receiving input parameters 302 associated with at least a portion of the power grid. The method 300 further comprises preparing an initial quantum state 304 associated with the one or more qubits based at least in part on the input parameters. The method 300 further comprises determining a plurality of time evolution steps 306, where each time evolution step of the plurality of time evolution steps is associated with a different respective iteration of a plurality of iterations. The method 300 also comprises applying, for each iteration of the plurality of iterations, a first set of quantum gate operations and a second set of one or more quantum gate operations 308. The method 300 further comprises determining the transient stability 310 of the power grid based at least in part on one or more properties of a quantum state produced by an iteration of the plurality of iterations.

Some quantum computers can comprise a system of qubits. In some examples, a quantum computer can initialize quantum states associated with each qubit of the system of qubits. Gate operations can then be used to manipulate the quantum states of the qubits and perform operations. These operations can be associated with simulating the real-time or imaginary-time evolution of a Hamiltonian.

As previously described, a first set of quantum gate operations can be performed on one or more qubits and can produce a quantum state that is based at least in part on a first evolution of an initial quantum state or a quantum state produced by a previous iteration of a plurality of iterations. This first evolution can be associated with a real-time evolution of the quantum state. Some implementations of quantum algorithms that can simulate real-time evolution on a quantum computer comprise gate operations performed on one qubit or two qubits. In some examples, these gate operations can be unitary such that a probability associated with a quantum state is conserved.

As previously described, a second set of quantum gate operations can produce a quantum state that is based at least in part on a second evolution of the quantum state produced by the first state of the one or more quantum gate operations of a respective iteration. This second evolution can be associated with an imaginary-time evolution of the quantum state. In some examples, imaginary-time evolution of a quantum state is non-unitary such that the probability associated with a quantum state is not conserved. In some examples, imaginary-time evolution can be simulated on a quantum computer using a combination of unitary gates and mid-circuit measurement techniques as described later.

In some examples, the first set of one or more quantum gate operations and the second set of one or more quantum gate operations can comprise one or more elementary gates such as an Rᵢ gate, a Controlled-Z gate (Z), a U gate, a Pauli gate, or a Controlled Not (CNOT) gate. Some Rᵢ gates can correspond to a single-qubit rotation of θ radians along an axis i of a Bloch sphere. Some U gates can correspond to a single-qubit rotation about an axis. Some Pauli gates can correspond to a single qubit rotation of It radians around an axis.

Some implementations of real-time evolution can involve a set of ancilla qubits to block encode the Hermitian operator that generates time evolution, the Hamiltonian, inside a unitary operator, which can then be transformed into a real-time evolution unitary by, e.g., quantum signal processing. In addition to the ancillas used for block encoding, each imaginary-time evolution step can comprise a probabilistically-successful measurement of an additional register of ancillas to perform a non-unitary evolution operator on the quantum computer. Implementing the total time evolution by alternating short fragments of real-and imaginary-time evolution can ensure that the success probability of each imaginary-time step is high.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A method for determining transient stability of a power grid using one or more qubits of a quantum computing system, the method comprising:
receiving input parameters associated with at least a portion of the power grid;
preparing an initial quantum state associated with the one or more qubits based at least in part on the input parameters;
determining a plurality of time evolution steps, where each time evolution step of the plurality of time evolution steps is associated with a different respective iteration of a plurality of iterations;
applying, for each iteration of the plurality of iterations,
a first set of one or more quantum gate operations to the one or more qubits, wherein the first set of one or more quantum gate operations produces a quantum state that is based at least in part on a first evolution of the initial quantum state or a quantum state produced by a previous iteration of the plurality of iterations, and
a second set of one or more quantum gate operations to the one or more qubits, wherein the second set of one or more quantum gate operations produces a quantum state that is based at least in part on a second evolution of the quantum state produced by the first set of one or more quantum gate operations of a respective iteration; and
determining the transient stability of the power grid based at least in part on one or more properties of a quantum state produced by an iteration of the plurality of iterations.

2. The method of claim 1, wherein the power grid comprises a plurality of nodes including one or more power supply nodes and one or more power consumption nodes interconnected by power transmission lines, the first evolution corresponds to propagation of waveforms over one or more of the power transmission lines.

3. The method of claim 2, wherein the second evolution corresponds to damping of waveforms at one or more of the plurality of nodes.

4. The method of claim 1, wherein the input parameters are based at least in part on a Kuramoto model.

5. The method of claim 1, wherein the first evolution of the initial quantum state or a quantum state produced by a previous iteration of the plurality of iterations corresponds to a real-time evolution of the initial quantum state or the quantum state produced by a previous iteration of the plurality of iterations.

6. The method of claim 5, wherein the second evolution of the quantum state produced by the first set of one or more quantum gate operations of a respective iteration corresponds to an imaginary-time evolution of the quantum state produced by the first set of one or more quantum gate operations of a respective iteration.

7. The method of claim 1, wherein the one or more qubits comprises at least two qubits and a first quantum gate operation of the second set of one or more quantum gate operations comprises entangling a first subset of the at least two qubits with a second subset of the at least two qubits.

8. The method of claim 7, wherein a second quantum gate operation of the second set of one or more quantum gate operations comprises measuring one or more quantum states, where each quantum state is associated with a respective qubit of the first subset of the at least two qubits.

9. The method of claim 8, wherein the second set of one or more quantum gate operations produces the quantum state based at least in part on a result of the measurement of the one or more quantum states.

10. The method of claim 1, wherein at least one quantum gate operation of the first set of one or more quantum gate operations comprises a rotation operation to one or more qubits.

11. The method of claim 10, wherein at least one quantum gate operation of the first set of one or more quantum gate operations comprises a controlled unitary operation between a first qubit of the one or more qubits and a second qubit of the one or more qubits.

12. The method of claim 11, wherein the first set of one or more quantum gate operations comprises alternating controlled unitary operations between the first qubit of the one or more qubits and the second qubit of the one or more qubits and rotation operations applied to the second qubit of the one or more qubits.

13. The method of claim 12, wherein the controlled unitary operations comprise controlled not (CNOT) operations.

14. The method of claim 1, wherein the second set of quantum gate operations comprises Hadamard gates applied to each qubit of the one or more qubits.

15. The method of claim 1, wherein each gate operation of the first set of one or more quantum gate operations is applied to either one qubit of the one or more qubits or two qubits of the one or more qubits.

16. A system configured for determining transient stability of a power grid using one or more qubits of a quantum computing system, the system comprising:
a power grid comprising one or more power supply nodes and one or more power consumption nodes interconnected by power transmission lines;
an interface module in communication with the quantum computing system configured to manage an analysis process, the management comprising:
receiving input parameters associated with at least a portion of the power grid;
preparing an initial quantum state associated with the one or more qubits based at least in part on the input parameters;
determining a plurality of time evolution steps, where each time evolution step of the plurality of time evolution steps is associated with a different respective iteration of a plurality of iterations;
sending to the quantum computing system a specification defining the plurality of iterations performed by the quantum computing system, wherein each iteration of the plurality of iterations comprises,
a first set of one or more quantum gate operations applied to the one or more qubits, wherein the first set of one or more quantum gate operations produces a quantum state that is based at least in part on a first evolution of the initial quantum state or a quantum state produced by a previous iteration of the plurality of iterations, and
a second set of one or more quantum gate operations applied to the one or more qubits, wherein the second set of one or more quantum gate operations produces a quantum state that is based at least in part on a second evolution of the quantum state produced by the first set of one or more quantum gate operations of a respective iteration; and
determining the transient stability of the power grid based at least in part on a result received by the quantum computing system indicating one or more properties of a quantum state produced by an iteration of the plurality of iterations.

17. The system of claim 16, wherein the first evolution corresponds to propagation of waveforms over one or more of the power transmission lines.

18. The system of claim 16, wherein the second evolution corresponds to damping of waveforms at one or more of the plurality of power supply nodes.

19. The system of claim 16, wherein the input parameters are based at least in part on a Kuramoto model.

20. The system of claim 16, wherein the first evolution of the initial quantum state or a quantum state produced by a previous iteration of the plurality of iterations corresponds to a real-time evolution of the initial quantum state or the quantum state produced by a previous iteration of the plurality of iterations.
